(19) United States
(12) Patent Application Publication
(10) Pub. No.: US 2020/0083401 A1
(43) Pub. Date: Mar. 12, 2020

(54) METHOD FOR PRODUCING LIGHT-EMITTING SEMICONDUCTOR COMPONENTS AND LIGHT-EMITTING SEMICONDUCTOR COMPONENT

(71) Applicant: OSRAM Opto Semiconductors GmbH, Regensburg (DE)

(72) Inventors: David O'BRIEN, Bad Abbach (DE); Britta GOEOETZ, Regensburg (DE); Norwin VON MALM, Nittendorf (DE)

(73) Assignees: OSRAM Opto Semiconductors GmbH, Regensburg (DE); OSRAM Opto Semiconductors GmbH, Regensburg (DE)

(21) Appl. No.: 15/749,768

(22) PCT Filed: Aug. 10, 2016
(86) PCT No.: PCT/EP2016/069069

§ 371 Date: Feb. 1, 2018

(30) Foreign Application Priority Data
Aug. 26, 2015 (DE) 102015114175.2

(51) Int. Cl. H01L 33/00; H01L 33/50; H01L 33/54; H01L 33/06; H01L 51/56; H01L 27/32; H01L 51/52

(52) U.S. Cl. CPC H01L 33/0095; H01L 33/502; H01L 33/54; H01L 51/5246; H01L 51/56; H01L 27/322; H01L 33/06

(57) ABSTRACT

The invention relates, in one embodiment, to a method for producing light-emitting semiconductor components, which method comprises the following steps: A) providing a glass capillary (2) composed of a glass material, B) filling the glass capillary (2) with luminescent substances (3), C) sealing the glass capillary (2) in a sealing region (22) by melting the glass material such that the glass capillary (2) is closed by the glass material itself, and D) attaching the sealed glass capillary (2) to a light-emitting diode chip (4) such that the radiation emitted by the light-emitting diode chip (4) is converted into visible light by the luminescent substances (3) during operation, wherein in step C) a distance between the sealing region (22) and the luminescent substances (3) is at most 7 mm, and wherein the different luminescent substances (3) are separated from each other along a longitudinal axis (L) of the glass capillary (2).

The invention relates to a method for producing light-emitting semiconductor components. Furthermore, a light-emitting semiconductor component is specified.

The aim of the invention is to provide a method by means of which compact conversion elements for light-emitting semiconductor components can be produced efficiently.

This object is achieved, inter alia, by a method having the features of patent claim 1. Preferred further developments are the subject-matter of the further claims.

According to at least one embodiment, a light-emitting semiconductor component is produced using the method. The light-emitting semiconductor component is, for example, a light-emitting diode, LED for short, or a laser diode. In this case, the light-emitting semiconductor component has a light-emitting diode chip or laser diode chip as a light source. Alternatively, the method is used to produce a conversion element without its own primary light source.

According to at least one embodiment, the method comprises the step of providing at least one glass capillary. The glass capillary is formed from a glass material. Glass capillary means, in particular, that the glass capillary is of tubular design. A cross section of the glass capillary can be rectangular or round.

According to at least one embodiment, the glass capillary is filled with one or more phosphors. In this case, the glass capillary can be filled completely or, preferably, only in part with the phosphor.

According to at least one embodiment, the method comprises the step of sealing the glass capillary. The sealing is carried out in a sealing region. The glass capillary is thus closed in the sealing region.

According to at least one embodiment, the sealing of the glass capillary is a hermetic seal. In particular, sealing against moisture and oxygen is achieved by the sealing. Diffusion coefficients of oxygen and moisture through the seal are preferably smaller than the associated diffusion coefficients through untreated outer walls of the glass capillary. In particular, an average thickness of the seal lies above a mean wall thickness of the outer walls of the untreated glass capillary.

According to at least one embodiment, the sealing is carried out by melting or at least softening the glass material of the glass capillary. The glass capillary is then closed by the glass material itself. An additional sealing material is not required in this case.

According to at least one embodiment, at least one part of the sealed glass capillary is applied to at least one light-emitting semiconductor chip, in particular to a light-emitting diode chip. The application is done, for example, by adhesive bonding. Alternatively, it is also possible that the glass capillary is attached to the light-emitting semiconductor chip by partially melting the glass material.

According to at least one embodiment, primary radiation is emitted in the finished semiconductor component by the light-emitting diode chip during operation. The primary radiation is partially or completely converted into light of a greater wavelength by the phosphor, in particular into visible light. Thus, the at least one phosphor can be used to set a color impression of the overall radiation emitted by the semiconductor component.

According to at least one embodiment, a distance between the sealing region and the phosphor during, and preferably also after, the sealing of the glass capillary of the invention is at most 7 mm or 4 mm or 3 mm or 1 mm. In other words, the sealing is carried out close to the phosphor.

In at least one embodiment, the method is set up for producing light-emitting semiconductor components and comprises the following steps, preferably in the order specified:
A) Providing at least one glass capillary made of a glass material,
B) Filling the glass capillary with at least one phosphor,
C) Sealing the glass capillary in a sealing region by melting and/or softening the glass material, so that the glass capillary is closed by the glass material itself, wherein a distance between the sealing region and the phosphor is at most 4 mm, and
D) Attaching at least a part of the sealed glass capillary to at least one light-emitting semiconductor chip, which is preferably a light-emitting diode chip, so that the radiation emitted by the light-emitting semiconductor chip during operation is partially or completely converted into radiation of a greater wavelength, preferably into visible light.

Conventional phosphors for light-emitting diodes are inorganic, crystalline and/or vitreous materials such as, for example, YAG:Ce. However, a number of other phosphor classes, such as quantum dots or organic phosphors, have many advantages with regard to their optical properties compared with such conventional inorganic phosphors. In particular, such newer phosphors have a spectrally narrow-band emission, and a central wavelength of the phosphor emission can be set comparatively easily.

However, the applicability of such newer phosphor classes for light sources having a long service life has hitherto been greatly limited, since such phosphors usually exhibit a high sensitivity to moisture, oxygen and temperature effects. Such phosphors, in particular quantum dots, are therefore to be accommodated in a high-quality encapsulation, in order to protect the phosphor from environmental influences in the long term. But such an encapsulation of the phosphor is difficult to achieve using conventional encapsulation methods, such as used in light-emitting diode technology. A conventional encapsulation method consists in embedding a phosphor in a silicone matrix or an epoxy matrix.

In the case of unsuitable encapsulation, however, a serious degradation of such phosphors takes place, resulting in a considerable reduction in the service life of the phosphor and thus also of the component in which the phosphor is used. In addition, in conventional sealing methods, by means of which a high-quality encapsulation is produced, usually high temperatures are required, which can severely impair or destroy such a phosphor during the production of the encapsulation.

Using the method described here, it is possible to seal temperature-sensitive phosphors in capillaries made from a glass with high quality. Thus, very compact conversion elements can be achieved.

Another way of sealing phosphors would be to encapsule phosphors in glass vessels. However, such glass vessels have comparatively large geometric dimensions and are therefore only suitable to a limited extent in conjunction with the construction of light-emitting diodes. A further way of sealing luminescent substances is to embed the latter between polymer films which are coated with an inorganic material. However, edges of such films are usually unprotected, which can lead to a significant degradation of the phosphor over time. As a result of the diffusion of moisture or oxygen over an edge or over edges of the film, the minimum dimensions of such films are also relatively large.

According to at least one embodiment of the method, the glass capillary is designed in such a way that only a comparatively small amount of heat is required for sealing and melting and/or softening the glass material. This can be achieved in particular by small average wall thicknesses of the glass capillary.

According to at least one embodiment, the glass capillary has, before step C), an average wall thickness of at most 125 μm or 100 μm or 80 μm or 55 μm. Alternatively or additionally, the average wall thickness is at least 20 μm or 40 μm. In other words, the glass capillary can then be a hollow glass wire. Due to the small average wall thickness, it is possible that the glass capillary, similarly to an optical waveguide, is mechanically flexible and bendable, for example with radii of curvature of 10 cm or less or of 5 cm or less. The glass capillary preferably has a constant wall thickness before step C) and thus without significant thickness fluctuations.

According to at least one embodiment, a duration of method step C) per sealing region is at most 6 s or 4 s or 2 s. Alternatively or additionally, this duration per sealing is at least 0.2 s or 0.5 s or 1 s. In this case, it is possible that a plurality of sealing regions are produced in parallel by melting or softening. As a result of this short processing duration, the thermal load on the phosphor is just small.

According to at least one embodiment, the phosphor is in a liquid state in method step B). This can mean that the phosphor itself is melted or liquid or that the luminescent substance is embedded in a liquid matrix material or is present in a solvent. The liquid forming the phosphor or the liquid comprising the phosphor is then introduced into the glass capillary.

According to at least one embodiment, after step B) the phosphor and/or the matrix material into which the phosphor is embedded is/are solidified. The solidification preferably takes place photochemically or by means of a drying process. For example, the matrix material is photochemically cured with ultraviolet radiation. It is likewise possible for the curing to be effected thermally. The matrix material is, for example, an acrylate, an ormocer, a silicone, an epoxide or a hybrid material. Ormocers are described, for example, in the publication WO 2013/156325 A1. The disclosure content of this publication with regard to the ormocers is incorporated by reference.

According to at least one embodiment, in step B) the matrix material or the liquid phosphor has a contact angle to the glass capillary which is at least 55° or 65° or 75° or 85°. Alternatively or additionally, the contact angle is at most 120° or 105° or 95°. In other words, the matrix material and the glass material are matched to one another in such a way that the contact angle due to the surface tension of the phosphor and/or of the matrix material is approximately 90°.

According to at least one embodiment, a quotient of a length of the glass capillary and a diameter of the glass capillary in the finished semiconductor component and/or in step D) is at least 15 or 20 or 25. Alternatively or additionally, this quotient is at most 150 or 100 or 70.

According to at least one embodiment of the method, the at least one phosphor which is present in the form of a liquid is injected into the glass capillary by means of a syringe. In this case, the syringe preferably moves along a longitudinal axis of the glass capillary in order to distribute the phosphor in a targeted manner along the glass capillary. As an alternative to an injection method, it is possible to fill the glass capillary with the phosphor by means of a vacuum method. In this case, a negative pressure is generated at one end of the glass capillary, for example, so that a phosphor moves into the glass capillary from the other end. Furthermore, it is possible for the glass capillary to be filled with the phosphor on account of capillary forces.

According to at least one embodiment, after step B) regions in the glass capillary filled with the phosphor and regions filled with a protective gas alternate with one another. The different regions preferably succeed one another alternatingly along the longitudinal axis. The protective gas is, for example, nitrogen or argon. In the regions filled with the protective gas, normal pressure is preferably present at room temperature.

According to at least one embodiment, the glass material is a borosilicate glass. Borosilicate glass can mean that a mass proportion of silicon dioxide in the glass material is at least 70% and a mass proportion of boron trioxide is at least 7%. In other words, the glass material is then a chemical-resistant glass having a comparatively high processing temperature.

According to at least one embodiment, in step C) the processing temperature of the glass material is at least 500° C. or 600° C. Alternatively or additionally, the processing temperature is at most 900° C. or 800° C. or 700° C. The processing temperature can be a melting temperature or a glass transition temperature of the glass material. Due to the comparatively high processing temperature, the glass material is, in particular, not a glass solder.

According to at least one embodiment, the glass material is a low-melting glass. In this case, a processing temperature of the glass material in step C) is at least 200° C. and/or at most 500° C.

According to at least one embodiment, the glass capillary is retained as a mechanical unit in step C). In other words, the glass capillary is not divided into individual sections by the sealing. In particular, the glass capillary can remain a mechanically self-supporting unit, so that a mechanical cohesion of the glass capillary is not or not significantly impaired by the sealing regions. In particular, no separation or melting takes place in step C). As an alternative to this, in step C) both sealing and separation can be carried out.

According to at least one embodiment, the glass capillary has, at least before step C), an inner space, the central cross-sectional area of which, in particular in the direction perpendicular to the longitudinal axis, is at least 0.2 mm×0.3 mm or 0.3 mm×0.4 mm and/or at most 3 mm×1.5 mm or 2 mm×1 mm or 1.5 mm×0.8 mm or 1.2 mm×0.6 mm. The cross-sectional area is in particular less than 4.5 mm² or 3 mm² or 1 mm² and/or at least 0.02 mm² or 0.1 mm² or 0.5 mm².

According to at least one embodiment, the cross-sectional area of the inner space is a rectangle or a rectangle with rounded corners. Alternatively, this cross-sectional area can also be shaped like a circle or an ellipse. Alternatively or additionally, an outer contour surface of the glass capillary, also seen in cross section, is a rectangle or a rectangle with rounded corners or also a semicircle. The outer contour of the glass capillary preferably has at least one straight boundary line, as seen in cross section, on which the at least one light-emitting semiconductor chip can be attached.

According to at least one embodiment, the melting or softening of the glass material takes place in step C) using at least one external electric heating wire lying outside the glass capillary. By means of such a heating wire, in particular a ring is formed, through which the glass capillary is guided. The heating wire is heated in the sealing regions, thus bringing about the processability of the glass material.

As an alternative to a heating wire, the sealing region can also be produced by a flame, for example by means of a gas flame, or by means of laser radiation. In particular, near-infrared laser radiation is used in the case of laser radiation. Alternatively, it is also possible for the glass capillary itself to be provided with a heating wire, which is located in subsequent sealing regions. Such a heating wire of the glass capillary can, for example, be embedded in the glass material or applied to outer walls of the glass capillary.

According to at least one embodiment, a plurality of different phosphors are introduced into the glass capillary in step B). In this case, the phosphors are preferably separated from one another along the longitudinal axis of the glass capillary. The different phosphors can touch each other or can be separated from one another by an intermediate space, in particular filled with the protective gas. The different phosphors are designed, for example, to generate differently colored light from the radiation of the light-emitting diode chip, for example blue light, green light and/or red light.

According to at least one embodiment, the method comprises an additional step, step E). In step E), the glass capillary is separated into conversion elements. This step E) preferably follows step C) and/or step D).

According to at least one embodiment, the separation in step E) takes place in the sealing regions. In this case, the seal remains intact, preferably on both sides of a separating line along which the separation takes place.

According to at least one embodiment, a plurality of the sealing regions are present along the longitudinal axis, in particular at least three or ten or 20 sealing regions. Part of the phosphor filled into the glass capillary can be located between adjacent sealing regions in each case.

According to at least one embodiment, a plurality of the separating regions are present both along the longitudinal direction and along a transverse axis. The transverse axis is preferably oriented perpendicular to the longitudinal axis. A two-dimensional arrangement of regions with the phosphor is thus present.

According to at least one embodiment, in step D) a two-dimensional array of light-emitting diode chips is applied to the two-dimensional arrangement of phosphor regions. The light-emitting diode chips can be applied individually or, preferably, in a composite, so that the light-emitting diode chips are pre-assembled, for example, on a printed circuit board.

According to at least one embodiment, at least one indicator for the presence of moisture, oxygen or elevated temperature is introduced into the glass capillary in step B). Alternatively, this introduction can already take place before step B). The indicator can determine whether moisture is present in the glass capillary or whether oxygen has penetrated into the glass capillary. It is likewise possible to monitor via an indicator whether a maximum temperature permissible for the phosphor has been maintained in the course of the production process.

According to at least one embodiment, one or more trapping materials are introduced into the glass capillary before or in step B). Oxygen and/or moisture can preferably be adsorbed by the at least one trapping material.

According to at least one embodiment, an opaque, preferably reflecting coating is applied to the outside or inside of the glass capillary in places. An emission characteristic of light from the glass capillary can be adjusted by means of such a coating.

According to at least one embodiment, the glass capillary is formed at least in regions as an optical element. In particular, the glass capillary is designed as a converging lens for the light emitted by the phosphor.

Furthermore, a light-emitting semiconductor component is specified. The semiconductor component is preferably produced using a method as specified in connection with one or more of the above-mentioned embodiments. Features of the semiconductor component are therefore also disclosed for the method and vice versa.

In at least one embodiment, the semiconductor component comprises at least one light-emitting diode chip or a light-emitting semiconductor chip and at least one glass capillary, in this context, the term glass capillary is also referred to as a conversion element. The at least one glass capillary is filled at least in part with a phosphor. A distance between a sealing region of the glass capillary and the phosphor is at most 4 mm or at most 2 mm.

According to at least one embodiment, the phosphor in the glass capillary is designed to convert blue light into yellow light. As a result, it is possible for the semiconductor component to emit mixed-colored light, in particular white light, during operation.

According to at least one embodiment, a plurality of light-emitting semiconductor chips, in particular light-emitting diode chips, are present. The light-emitting diode chips are arranged in a straight strip and the glass capillary covers the strip. In this case, each of the light-emitting diode chips is preferably assigned exactly to one region in the glass capillary which is filled with the phosphor. Adjacent phosphor regions are preferably separated from one another and can be optically isolated from one another, for example by means of an opaque intermediate material filled into the glass capillary.

According to at least one embodiment, the glass capillary is mechanically fixedly connected to the strip. For example, the glass capillary is adhesively bonded to the light-emitting semiconductor chips on the strip or fused to the strip.

Furthermore, a conversion element is specified. The conversion element is produced using a method as indicated in connection with one or more of the above-mentioned embodiments. Features of the method and of the light-emitting semiconductor component are therefore also disclosed for the conversion element and vice versa. In particular, the conversion element is a component which corresponds to the light-emitting semiconductor component without the at least one light-emitting diode chip and without a connecting means between the light-emitting diode chip and the glass capillary. In other words, the conversion element is the sealed and optionally isolated glass capillary filled with phosphor.

In the following, a method described here, a light-emitting semiconductor component described here and a conversion element described here are explained in more detail with reference to the drawings on the basis of exemplary embodiments. Identical reference characters indicate the same elements in the individual figures. In this case, however, no relationships to scale are illustrated; rather, individual elements can be represented with an exaggerated size in order to afford a better understanding.

In the Drawings:

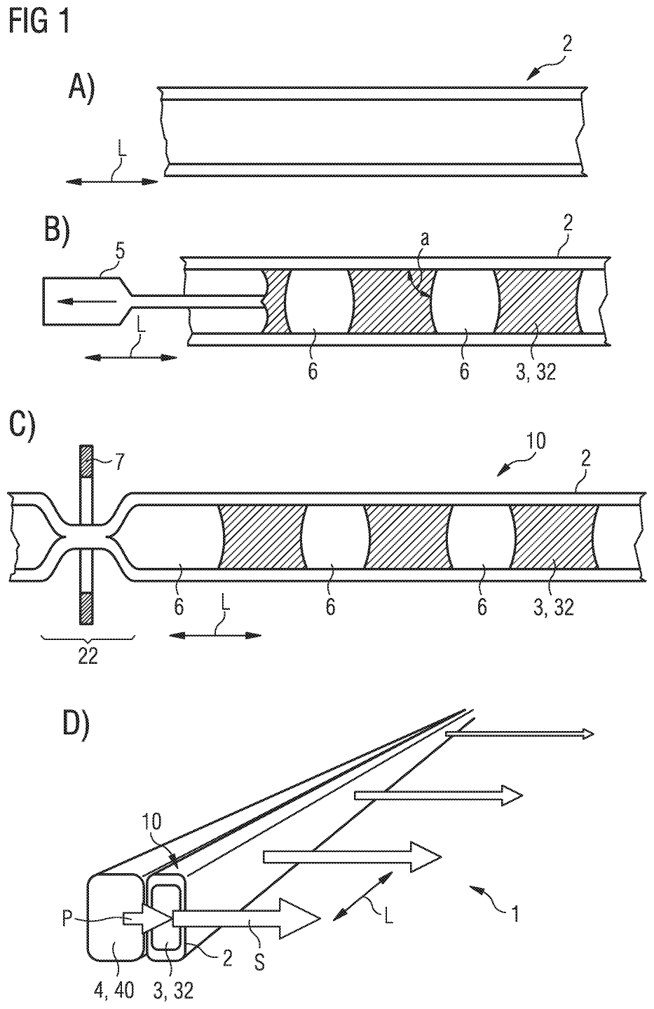

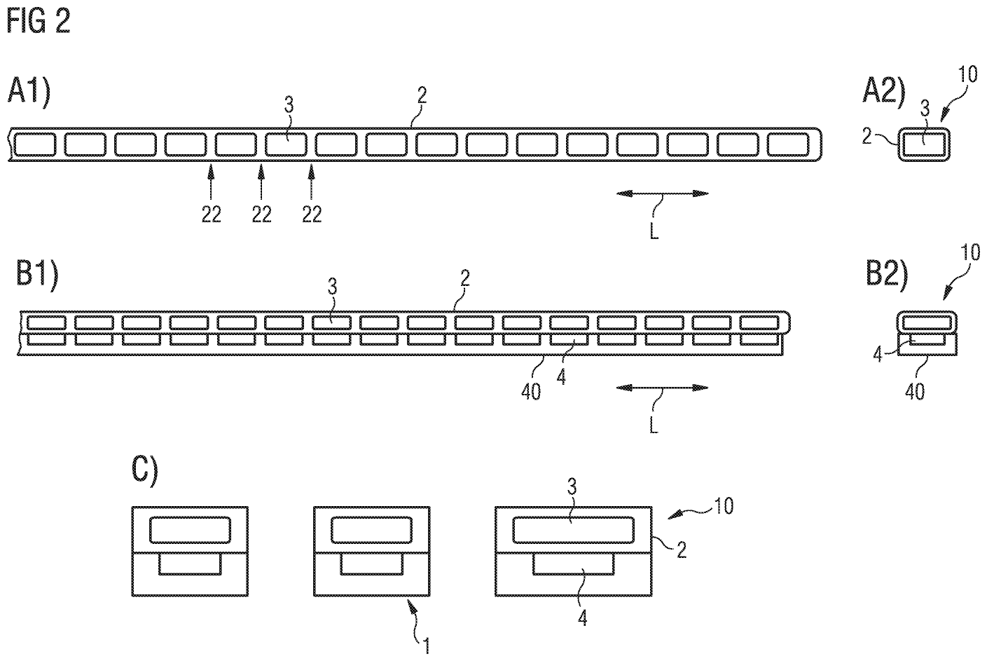

FIGS. 1 and 2 show schematic illustrations of exemplary embodiments of methods for producing light-emitting semiconductor components described here, and

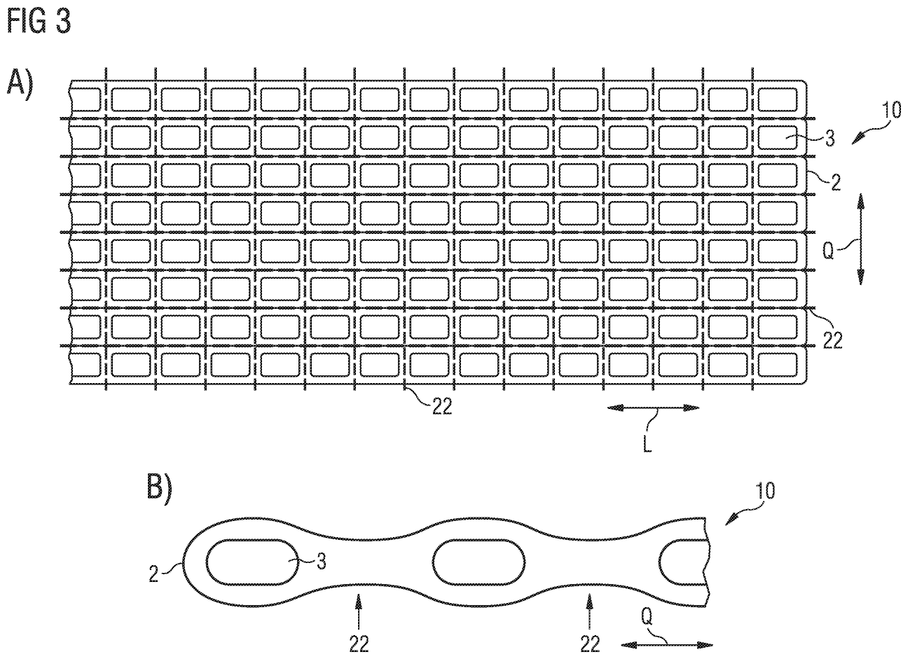

FIGS. 3 to 7 show schematic representations of exemplary embodiments of conversion elements for light-emitting semiconductor components described here.

FIG. 1 illustrates an exemplary embodiment of a production method for a light-emitting semiconductor component 1, see the sectional representations of FIGS. 1A to 1C and the perspective representation in FIG. 1D.

According to FIG. 1A, a glass capillary 2 is provided. The glass capillary 2 is of tubular design with a longitudinal axis L along which the glass capillary 2 has its greatest geometric extent. Viewed in cross section, the glass capillary 2 is designed to be rectangular, see also FIG. 1D. A wall thickness of the glass capillary 2 is below 100 μm, for example 60 μm, and is constant along the longitudinal axis L. An inner cross-sectional area of the glass capillary 2 is, for example, approximately 1.5 mm², outer dimensions of the glass capillary 2 are 1 mm×2 mm, for example.

In the method step as illustrated in FIG. 1B, a phosphor 3 is introduced into the glass capillary 2. The phosphor 3 is introduced by means of a syringe 5, which moves along the longitudinal axis L in order to introduce the phosphor 3 locally in a targeted manner.

The phosphor 3 is preferably realized by quantum dots, for example based on cadmium selenide or indium phosphide. The quantum dots preferably have an average diameter of at least 3 nm or 5 nm and/or of at most 30 nm or 15 nm. The phosphor 3 is present in a matrix material 32. The matrix material 32 with the phosphor 3 is introduced into the glass capillary 2 in liquid form. In this case, this liquid, consisting of the matrix material 32 and the phosphor 3, preferably completely fills the cross section of the glass capillary 2 in places. The glass capillary 2 is filled only partly by the liquid. A protective gas, for example nitrogen, is preferably located between adjacent regions with the phosphor 3.

A contact angle a between the walls of the glass capillary 2 and the still liquid matrix material 32 is approximately 90°. In this way, an interaction of adjacent regions with the phosphor 3 can be prevented. The matrix material 32 is, for example, a photochemically curable acrylate.

Instead of quantum dots, other phosphors such as organic phosphors, in particular in the matrix material 32, can also be used.

After the phosphor 3 has been introduced, the matrix material 32 is cured, not illustrated. The curing is carried out in particular by irradiation with ultraviolet light. As a result, thermal loading of the phosphor during curing can be avoided.

Subsequently, see FIG. 1C, a glass material, from which the glass capillary is made, is melted or at least softened in a sealing region 22. The melting or softening preferably takes place by means of a heating wire 7 through which the glass capillary 2 is guided.

Owing to the small wall thickness of the glass capillary 2, in particular, the sealing region 22 is comparatively small in the direction parallel to the longitudinal axis L. Likewise, only a short period of time is required in which the heating wire 7 is activated via an electric current flow. Since only a comparatively small amount of heat is required for producing the seal in the sealing region 22, the phosphor 3 is exposed to only low thermal loads. As a result, a particularly small distance between the sealing region 22 and the closest phosphor 3 can also be achieved. This distance is preferably 1 mm or less.

Deviating from the representation in FIG. 1C, it is optionally possible that a cooling device is located outside the sealing region 22 at or near an outer boundary surface of the glass capillary 2. By means of such a cooling device, heat can be efficiently dissipated from the glass material outside the sealing region 22. Such a cooling device is preferably also impermeable to infrared radiation, so that, starting from the heating wire 7, no radiation heat input into the glass capillary 2 takes place outside the sealing region 22 or into the phosphor 3. Such a cooling device (not shown) is preferably also present in all other exemplary embodiments.

Furthermore, it is optionally possible, in contrast to the drawing, that, when the sealing region 22 is produced, the glass capillary 2 is pressed together locally and/or that the parts of the glass capillary 2 located on both sides of the sealing region 22 are twisted relative to one another. For this purpose, a cooling device can also be attached to the glass capillary 2 near the sealing region 22.

It is also possible, in a departure from the representation in FIG. 1, that the sealing region 22 is located on an outer edge and is not located in a central section of the glass capillary 2 along the longitudinal axis L. For example, the glass capillary 2 is then only sealed at two mutually opposite ends.

In the method step of FIG. 1D, it is shown that the conversion element 10 formed in the step of FIG. 1C is applied to a strip 40. The strip 40 comprises a plurality of light-emitting diode chips 4, which emit a primary radiation P, preferably blue light, during operation. The light-emitting diode chips 4 are electrically connected to one another, for example via conductor tracks or via a printed circuit board of the strip 40.

Only part of the primary radiation P is absorbed by the phosphor 3 in the interior of the glass capillary 2 and converted into a secondary radiation S. In this way, the semiconductor component 1 can emit white light, for example.

A length of the semiconductor component 1 along the longitudinal axis L is, for example, at least 5 cm or 10 cm and/or at most 30 cm or 20 cm. The semiconductor component 1 can be a strip-shaped light source for backlighting displays in combination with a surface light guide (not shown).

In the exemplary embodiment of FIG. 2, a plurality of sealing regions 22 are present, between each of which a phosphor 3 is located, see the sectional representation along the longitudinal axis L in FIG. 2A1 and the cross-sectional representation in FIG. 2A2.

Said conversion element 10 with the plurality of chambers is subsequently applied to the strip 40 with the light-emitting diode chips 4, see FIGS. 2B1 and 2B2. In this case, precisely one of the chambers with the phosphor 3 is assigned to each of the light-emitting diode chips 4.

FIG. 2C shows that the strip 40 with the glass capillary 2 is singulated to form the individual semiconductor components 1, for example by sawing, breaking in combination with scribing or by laser cutting. The singulation into the semiconductor components 1 takes place in the sealing regions 22, wherein the sealing of the chambers with the phosphor 3 remains intact in each case. According to FIG. 2C, each of the semiconductor components 1 comprises exactly one of the light-emitting diode chips 4; in contrast to this, however, it is also possible for a plurality of the light-emitting diode chips 4 to be present in the finished semiconductor components 1.

The chambers with the phosphor 3 preferably completely cover the associated light-emitting diode chip 4, seen in plan view. This ensures that the complete light-emitting diode chip 4 is covered by the phosphor 3 and homogeneously emits white light, for example. Lateral dimensions of the conversion element 10 are preferably equal to lateral dimensions of a housing for the light-emitting diode chips 4. Thus, no enlargement of a lateral extent is effected by the conversion element 10.

FIG. 3 illustrates a further conversion element 10. The glass capillary 2 is a rectangular tube with an elongated rectangular cross section before the sealing. The sealing regions 22 extend along the longitudinal axis L and along a transverse axis Q perpendicular to the longitudinal axis L. In the plan view of FIG. 3A, the sealing regions 22 are symbolized by dashed lines. FIG. 3B shows a cross-sectional illustration.

A two-dimensional arrangement of regions with the phosphor 3 can be realized by means of such a glass capillary 2. Such a two-dimensional arrangement of the regions with the phosphor 3 can be applied to a two-dimensional array of the light-emitting diode chips 4, not shown. Alternatively, the conversion element 10 can also be singulated along the sealing regions 22, analogously to FIG. 2C.

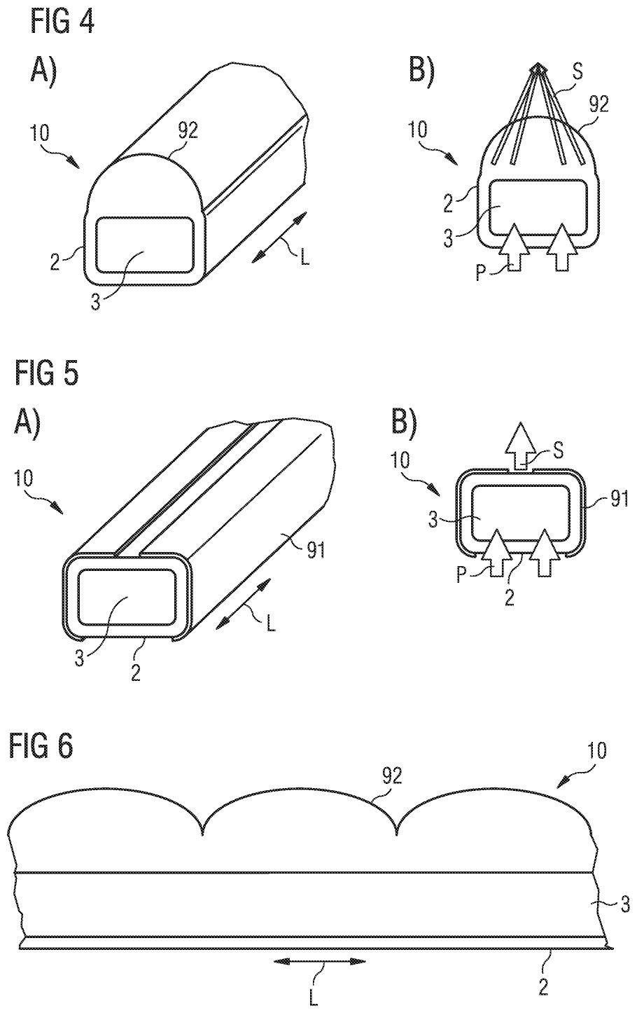

FIGS. 4 to 6 show further embodiments of the conversion element 10. According to FIG. 4, see the perspective illustration in FIG. 4A and the sectional illustration in FIG. 4B, the glass capillary 2 has an optical element 92. The optical element is designed as a converging lens which extends uniformly along the longitudinal axis L. A side of the glass capillary 2 opposite the lens 92 is of flat design and is designed such that the light-emitting diode chips 4 can be attached thereto. As illustrated in FIG. 4B, a beam shaping of the secondary radiation S can be achieved by means of such a lens 92.

In the exemplary embodiment of FIG. 5, an opaque, reflective or else absorbing coating 91 is applied in places on the outer surface of the glass capillary 2. The coating 91 is formed, for example, from one or more metals.

On an underside, which the light-emitting diode chips 4 are designed to be mounted on, no coating is applied to the glass capillary 2. On an upper side, a region is left free in the form of a strip, in order to allow the secondary radiation S and/or remaining parts of the primary radiation P to emerge from the glass capillary 2.

The coating 91 or the optical element 92 of FIGS. 4 and 5 extend uniformly along the longitudinal axis L. In FIG. 6, a sectional view deviating therefrom, it is shown that individual lenses or optical elements 92 can also be formed along the longitudinal axis L. The same is also possible with regard to the coating 91 from FIG. 5.

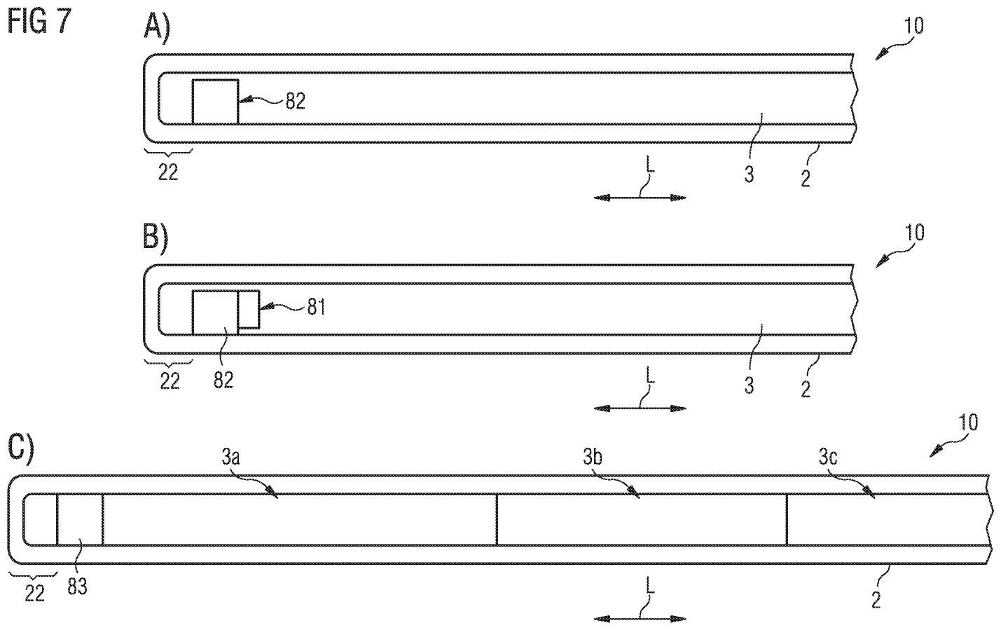

FIG. 7 shows further sectional representations of exemplary embodiments of the conversion element 10. In order to simplify the illustration, in each case only one sealing region 22 is shown at one end of the glass capillary 2. Sealing regions and geometries of the glass capillary 2 as illustrated in conjunction with FIGS. 1 to 6, preferably as explained in conjunction with FIG. 2 or 3, can also be present in connection with FIG. 7.

According to FIG. 7A, one end of the glass capillary 2 located close to the sealing region 22 is provided with a capturing material 82, also referred to as a getter. By means of the capturing material 82, moisture or oxygen can be removed from the remaining volume of the glass capillary 2.

According to FIG. 7B, an indicator material 81 is located in the glass capillary 2. The indicator material 81 can be used to identify whether oxygen or moisture is present in the glass capillary and/or whether a permissible, maximum processing temperature during the production of the sealing region 22 has been complied with. Such an indicator material 81 can also be present in combination with a capturing material 82.

Likewise, as an alternative to the capturing material 82 or the indicator material 81, an insulating element 83 near the sealing region 22 is introduced into the glass capillary 2, see FIG. 7C. The insulating element 83 is preferably thermally insulating and can be opaque. As a result, the phosphor 3 can be better protected against overheating when the sealing region 22 is produced.

The insulating element 83 is preferably made of a solid material, alternatively from a liquid, and is preferably introduced into the glass capillary 2 at a distance of at most 1 mm or 0.5 mm to the sealing region 22 or directly to the sealing region 22. The insulating element 83 preferably seals the glass capillary 2, so that the insulating element 83 extends over the entire inner region of the glass capillary 2, seen in cross section. A specific thermal conductivity of the material of the insulating element 83 is preferably at most 0.5 W/K·m or 0.2 W/K·m or 0.05 W/K·m.

Furthermore, three different phosphors 3a, 3b, 3c with different emission properties are introduced into the glass capillary 2, succeeding one another directly along the longitudinal axis L. For example, the phosphors 3a, 3b, 3c generate blue, green and red light, for example after excitation with primary radiation from the near ultraviolet spectral range or after excitation with blue light, for example with a dominant wavelength of 450 nm, for example with a tolerance of 5 nm. It is possible that the phosphor 3a is in direct contact with the insulating element 83. The phosphors 3a, 3b, 3c can touch one another or can be spaced apart from one another. A plurality of phosphors can also be present in all other exemplary embodiments.

The invention described here is not restricted by the description on the basis of the exemplary embodiments. Rather, the invention encompasses any new feature and also any combination of features, which includes in particular any combination of features in the patent claims, even if this feature or this combination itself is not explicitly specified in the patent claims or exemplary embodiments.

This patent application claims the priority of German patent application 10 2015 114 175.2, the disclosure content of which is hereby incorporated by reference.

### LIST OF REFERENCE NUMERALS

1 Light-emitting semiconductor component
2 Glass capillary
22 Sealing region
3 Luminescent substance
32 Matrix material
4 Light-emitting diode chip
40 Strip
5 Syringe
6 Protective gas
7 Electric heating wire
81 Indicator
82 Capture material
83 Insulating element
91 Light-opaque, reflective coating
92 Optical element
10 Conversion element
a Contact angle
L Longitudinal axis
P Primary radiation
Q Transverse axis
S Secondary radiation

1. Method for producing light-emitting semiconductor components comprising the following steps:
A) Providing at least one glass capillary made of a glass material,
B) Filling the glass capillary with several different phosphors,
C) Sealing the glass capillary in a sealing region by melting and/or softening the glass material, so that the glass capillary is closed by the glass material itself, and
D) Attaching at least a part of the sealed glass capillary to at least one light-emitting diode chip, so that, during operation, the radiation emitted by the light-emitting diode chip is partially or completely converted into light of a greater wavelength by the phosphors, wherein in step C) a distance between the sealing region and the phosphors is at most 4 mm, and
wherein the different phosphors are present separated from one another along a longitudinal axis of the glass capillary,
wherein the phosphors are introduced into the glass capillary by means of a syringe or by means of a vacuum method, so that in the glass capillary, after step B), regions filled with the phosphors and regions filled with a protective gas alternate with one another.

2. The method according to claim 1, wherein the glass capillary (2) has an average wall thickness of at least 20 μm and of at most 125 μm before step C),
wherein a duration of the method step C) per sealing region is at most 4 s, and wherein the phosphors are quantum dots or organic molecules.

3. The method according to claim 1, wherein in step B) the phosphors are in a liquid matrix material which is introduced into the glass capillary,
wherein the matrix material is subsequently photochemically or thermally cured.

4. The method according to claim 3, wherein in step B) the matrix material forms a contact angle to the glass capillary of at least 65° and of at most 105°,
wherein a quotient of a length of the glass capillary and a diameter of the glass capillary is at least 15 and at most 150.

5. The method according claim 3, wherein the matrix material is an acrylate, an ormocer, a silicone or an epoxide.

6. The method according to claim 1, wherein the glass material comprises a light-transmissive borosilicate glass with mass fractions of at least 70% of silicon dioxide and at least 7% of boron trioxide,
wherein a processing temperature of the glass material in step C) is at least 500° C. and at most 900° C.,
wherein, in step C), the glass capillary is maintained as a mechanically self-supporting unit, so that no separation or melting takes place in step C).

7. The method according to claim 1, wherein the glass material is a low-melting glass and a processing temperature of the glass material in step C) is at least 200° C. and at most 500° C.

8. The method according to claim 1, wherein, prior to step C), an average cross-sectional area of an interior of the glass capillary is at least 0.2 mm×0.3 mm and at most 1.5 mm×0.8 mm,
wherein the cross-sectional area is a rectangle or a rectangle with rounded corners.

9. The method according to claim 1, wherein the melting in step C) is performed with at least one external electric heating wire lying outside the glass capillary.

10. The method according to claim 1, wherein the glass capillary, viewed in cross section, has a plurality of adjacent inner spaces which are each filled with the phosphors.

11. The method according to claim 1, wherein exactly three different phosphors with different emission characteristics are introduced in the glass capillary, the phosphors immediately succeeding one another along the longitudinal axis,
wherein the phosphors independently from one another generate blue, green and red light, after excitation with a primary radiation from the near ultraviolet spectral range or after excitation with blue light,
wherein at a distance of at most 0.5 mm from the sealing region an insulating element is introduced into the glass capillary, the insulating element being thermally insulating and being opaque, so that the phosphors are protected from overheating during the formation of the sealing region, and
wherein one of the phosphors is in direct contact with the insulating element and the phosphors touch one another.

12. The method according to claim 1, further comprising a step E), in which the glass capillary is singulated into conversion elements,
wherein step E) follows step C) and/or step D).

13. The method according to claim 12, wherein, along the longitudinal axis, a plurality of the sealing regions is present and between at least some adjacent sealing regions part of the phosphors is located, wherein the singulation in step E) takes place in at least some of the sealing regions.

14. The method according to claim 13, wherein both along the longitudinal direction and along a transverse axis a plurality of the sealing regions is present, such that there is a two-dimensional arrangement of regions with the phosphors,
wherein a two-dimensional array of light-emitting diode chips is applied to said two-dimensional arrangement in step D).

15. The method according to claim 1, wherein, in step B), in the glass capillary at least one indicator for at least one of the variables of moisture content, oxygen content and maximum temperature and alternatively or additionally at least one trapping capturing material for oxygen or moisture is introduced.

16. The method according to claim 1, wherein an opaque, reflective coating is arranged on an outside of the glass capillary or in which the glass capillary is formed at least in regions as an optical element.

17. Light-emitting semiconductor component, which is produced by a method according to claim 1, comprising
at least one light-emitting diode chip, and
at least one glass capillary, which is at least partially filled with a plurality of phosphors, wherein a distance between a sealing region of the glass capillary and the phosphors is at most 4 mm, and
wherein the different phosphors are separated from one another along a longitudinal axis of the glass capillary.

18. Light-emitting semiconductor component according to the claim 17,
wherein one of the phosphors is designed to convert blue light into yellow light,
wherein the light-emitting diode chips are arranged in a straight strip and the glass capillary covers the strip and is mechanically fixedly connected to the strip.

19. Method for producing light-emitting semiconductor components comprising the following steps:
A) Providing at least one glass capillary made of a glass material,
B) Filling the glass capillary with several different phosphors,
C) Sealing the glass capillary in a sealing region by melting and/or softening the glass material, so that the glass capillary is closed by the glass material itself, and
D) Attaching at least a part of the sealed glass capillary to at least one light-emitting diode chip, so that, during operation, the radiation emitted by the light-emitting diode chip is partially or completely converted into light of a greater wavelength by the phosphors,
wherein in step C) a distance between the sealing region and the phosphors is at most 4 mm, and wherein the different phosphors are present separated from one another along a longitudinal axis of the glass capillary.
